(19) United States
(12) Patent Application Publication
(10) Pub. No.: US 2020/0075660 A1
(43) Pub. Date: Mar. 5, 2020

(54) SOLID-STATE IMAGE PICKUP DEVICE

(71) Applicant: OLYMPUS CORPORATION, Tokyo (JP)

(72) Inventors: Yusaku Koyama, Tokyo (JP); Jun Aoki, Tokyo (JP)

(73) Assignee: OLYMPUS CORPORATION, Tokyo (JP)

(21) Appl. No.: 16/674,205

(22) Filed: Nov. 5, 2019

Related U.S. Application Data
(63) Continuation of application No. PCT/JP2017/018025, filed on May 12, 2017.

(51) Int. Cl. H01L 27/146

(52) U.S. Cl. CPC H01L 27/14641; H01L 27/14603; H01L 27/14621; H01L 27/1463

(57) ABSTRACT

A solid-state image pickup device is provided with a two-dimensional pixel array wherein unit pixels are arrayed on a semiconductor substrate, the unit pixels respectively including photoelectric conversion elements configured to convert inputted light into electric signals, and circuit elements configured to read out the electric signals thus converted. The unit pixels are formed in at least one shared well region surrounded by an insulating element isolation region that penetrates the semiconductor substrate from the front surface to the rear surface and isolates the elements from each other. Each shared well region is biased to a predetermined potential via well contact sections of a number that is smaller than that of the unit pixels.

### CROSS REFERENCE TO RELATED APPLICATIONS

This application is a continuation application based on a PCT Patent Application No. PCT/JP2017/018025, filed on May 12, 2017, the content of which is incorporated herein by reference.

### BACKGROUND

### Technical Field

The present invention relates to a solid-state image pickup device. More specifically, the present invention relates to a solid-state image pickup device in which a plurality of unit pixels are arranged in a two-dimensional matrix on a semiconductor substrate.

### Background Art

In general, in a solid-state image pickup device or an image sensor, signal charges generated and accumulated by photoelectric conversion elements of pixels on which light is incident are guided to an amplifying unit provided in the pixel, and a signal amplified by the amplifying unit is output from the pixel. Some solid-state image pickup devices and image sensors using a semiconductor substrate include a pixel array in which a plurality of unit pixels are arranged in a two-dimensional matrix on the semiconductor substrate. In such a solid-state image pickup device or image sensor, in order to reduce electrical and optical crosstalk between adjacent pixels, that is, color mixing, for example, Japanese Unexamined Patent Application, First Publication No. 2009-206356 (hereinafter referred to as Patent Document 1) discloses a configuration (Full Deep Trench Isolation (FDTI)) in which a groove in an insulating layer is provided between adjacent pixels from the front surface to the rear surface of the silicon layer of the semiconductor substrate.

FIG. 9 is a cross-sectional view showing a configuration of a pixel array in the solid-state image pickup device of Patent Document 1. As shown in FIG. 9, in the semiconductor substrate 404, a plurality of unit pixels 1 are arranged in a two-dimensional matrix. On the surface of the semiconductor substrate 404, the unit pixel 1 includes a wiring layer 402 provided in the interlayer insulating film 409. On the rear surface of the semiconductor substrate 404, the unit pixel 1 includes a diffusion layer 403 that accumulates signal charges, an antireflection film 405, a color filter 406, a microlens 407, and an element isolation insulating film 408.

The element isolation insulating film 408 is provided at a boundary portion between adjacent unit pixels 1 on the semiconductor substrate 404 and insulates the unit pixels 1 from each other. The element isolation insulating film 408 is formed of an insulating film having a refractive index lower than that of the silicon layer of the semiconductor substrate 404.

In Patent Document 1, the color filter 406 of each unit pixel 1 is one of a color filter R that transmits light in the red wavelength region, a color filter G that transmits light in the green wavelength region, and a color filters B that transmits light in the blue wavelength region. Here, the unit pixel 1 having the color filter R is represented as R pixel, the unit pixel 1 having the color filter G is represented as G pixel, and the unit pixel 1 having the color filter B is represented as B pixel. Each of the R pixel, the G pixel, and the B pixel is insulated by an element isolation insulating film 408.

FIG. 10 is a plan view showing a configuration of a pixel array in the solid-state image pickup device of Patent Document 1. FIG. 9 is a cross-sectional view taken along the line VI-VI in FIG. 10. As shown in FIG. 10, a plurality of unit pixels 1 are arranged in a two-dimensional matrix on a semiconductor substrate 404. Each unit pixel 1 is insulated from each other by being surrounded by an element isolation insulating film 408 on all sides.

In the configuration of the pixel array of Patent Document 1, since the unit pixels 1 are insulated from each other by the element isolation insulating film 408, crosstalk and color mixing between unit pixels can be effectively prevented. However, in this configuration, since each unit pixel 1 is surrounded by the element isolation insulating film 408, the well contact for taking the reference potential of the pixel circuit in each unit pixel 1 must be arranged for each unit pixel 1, inside the region surrounded by the element isolation insulating film 408.

Therefore, according to the configuration of Patent Document 1, in the pixel array, the arrangement area of the well contact presses the arrangement area of transistors (for example, a reset transistor, an amplifier transistor, and a selection transistor) for driving the pixels. Furthermore, in the pixel array, the area of the well contact is also pressed against the area of the photodiode, so that the area and shape of the photodiode to be arranged are limited. For this reason, according to the structure of Patent Document 1, the number of saturated electrons and quantum efficiency of a pixel will fall and image quality will deteriorate.

According to a solid-state image pickup device of the present invention, while maintaining the crosstalk and color mixture between adjacent pixels efficiently, it is possible to maintain the saturated electron number and quantum efficiency of the pixel and prevent image quality deterioration.

### SUMMARY

A solid-state image pickup device includes a two-dimensional pixel array in which unit pixels are arranged on a semiconductor substrate, the unit pixels respectively including photoelectric conversion elements configured to convert inputted light into electric signals, and circuit elements configured to read out the electric signals that have been converted. The unit pixels are formed in at least one shared well region surrounded by an insulating element isolation region that penetrates the semiconductor substrate from front surface to rear surface and isolates elements from each other. Each of the shared well region is biased to a predetermined potential via well contact sections of a number that is smaller than that of the unit pixels.

Each of the well contact sections may be disposed at an intermediate portion between the unit pixels formed in the shared well region.

The number of the unit pixels formed in one shared well region may be two.

The number of the unit pixels formed in one shared well region may be four.

The unit pixels formed in at least one shared well region may be configured to have a color filter of one color.

The number of the well contact sections in one shared well region may be one, and the photoelectric conversion elements and the circuit elements of the unit pixels may be arranged symmetrically with respect to the well contact sections.

Color filters of the two unit pixels formed in one shared well region may be a combination that is less affected by color mixing depending on arrangement of the color filters in the pixel array.

Array of the color filters in the pixel array may be RGB Bayer array, and two G pixels located in a diagonal region in the pixel array may be formed in one shared well region.

According to a solid-state image pickup device of the above aspects of the present invention, while maintaining the crosstalk and color mixture between adjacent pixels efficiently, it is possible to maintain the saturated electron number and quantum efficiency of the pixel and prevent image quality deterioration.

### BRIEF DESCRIPTION OF THE DRAWINGS

FIG. 1A is a plan view showing a configuration of a pixel array in a solid-state image pickup device according to a first embodiment of the present invention.

FIG. 1B is a cross-sectional view showing a configuration of a pixel array in the solid-state image pickup device according to the first embodiment of the present invention.

FIG. 2 is a plan view showing a configuration of a pixel array in a solid-state image pickup device according to a second embodiment of the present invention.

FIG. 3 is a plan view showing a configuration of a pixel array in a solid-state image pickup device according to a third embodiment of the present invention.

FIG. 4 is a plan view showing a configuration of a pixel array in a solid-state image pickup device according to the third embodiment of the present invention.

FIG. 5A is a plan view showing a configuration of a pixel array in a solid-state image pickup device according to a fourth embodiment of the present invention.

FIG. 5B is a cross-sectional view showing a configuration of a pixel array in a solid-state image pickup device according to the fourth embodiment of the present invention.

FIG. 6 is a plan view showing a configuration of a pixel array in a solid-state image pickup device according to the fourth embodiment of the present invention.

FIG. 7 is a plan view showing a configuration of a pixel array in a solid-state image pickup device according to a fifth embodiment of the present invention.

FIG. 8 is a plan view showing a configuration of a pixel array in a solid-state image pickup device according to the fifth embodiment of the present invention.

FIG. 9 is a cross-sectional view showing a configuration of a pixel array in a solid-state image pickup device according to a conventional art.

FIG. 10 is a plan view showing a configuration of a pixel array in a solid-state image pickup device according to a conventional art.

### DETAILED DESCRIPTION OF THE PREFERRED EMBODIMENTS

Hereinafter, embodiments of the present invention will be described with reference to the drawings. The following description of the embodiments is intended to specifically describe the invention defined in the claims, and is not intended to limit the invention defined in the claims.

### First Embodiment

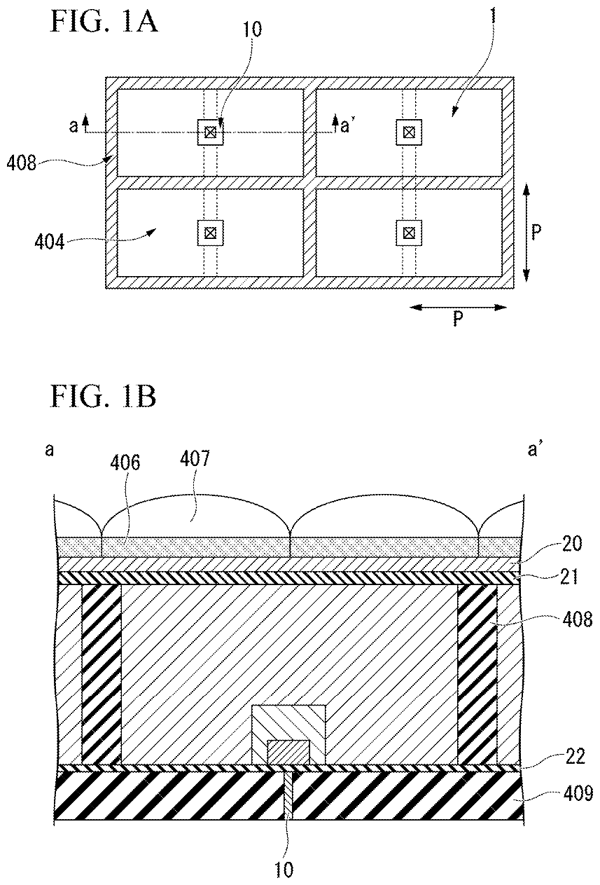

A first embodiment of the present invention will be described. FIG. 1A is a plan view showing a configuration of a pixel array in the solid-state image pickup device according to the first embodiment of the present invention. In the pixel array, the unit pixels 1 are two-dimensionally arranged on the semiconductor substrate 404. In the configuration of FIG. 1A, the unit pixels 1 are arranged in 2×4 pixels. The symbol P in the figure represents the pixel pitch of the unit pixel 1.

The element isolation insulating film (element isolation region) 408 is formed of an insulating film having a refractive index lower than that of the silicon layer of the semiconductor substrate. In Patent Document 1, the element isolation insulating film 408 is provided at all boundary portions between adjacent unit pixels 1 on the semiconductor substrate. However, in the first embodiment of the present invention, of the element isolation insulating film 408 surrounding each element pixel 1, the element isolation insulating film 408 (dotted line portion in the figure) on one side that separates adjacent unit pixels is omitted. The dotted line in the figure is for showing that the element isolation insulating film 408 is omitted, and there is nothing on an actual device.

Two unit pixels included in a region surrounded by the element isolation insulating film 408 share the well contact 10. Hereinafter, a region surrounded by the element isolation insulating film 408 is referred to as a “shared well region”. In the configuration of FIG. 1A, one shared well region includes two unit pixels. A well contact 10 shared by two unit pixels included in the shared well region is disposed in a region (dotted line portion in the drawing) from which the element isolation insulating film 408 is omitted. In the configuration of FIG. 1A, the well contact 10 is disposed at an intermediate portion between two unit pixels included in the shared well region.

FIG. 1B is a cross-sectional view showing the configuration of the pixel array in the solid-state image pickup device according to the first embodiment of the present invention. Specifically. FIG. 1B is a diagram showing a cross section taken along the line a-a′ of FIG. 1A. In the configuration of FIG. 1B, a circuit portion is formed on the surface side (lower side of the drawing) of the semiconductor substrate 404, and a gate insulating film 22 and an interlayer insulating film 409 are formed so as to cover the surface of the semiconductor substrate 404 and the circuit portion. Further, the rear surface side (upper side in the drawing) of the semiconductor substrate 404 is a light receiving surface, where the insulating film 21 and the planarizing film 20 are formed, and the color filter 406 and the microlens 407 are disposed.

The semiconductor substrate 404 is divided into a plurality of shared well regions insulated from each other by an element isolation insulating film 408. A contact P+ for supplying power to the P-well is provided on the front surface side (lower side of the drawing) of the semiconductor substrate 404. The well contact 10 is provided so as to penetrate the interlayer insulating film 409 downward from the contact P+.

As described above, in the configuration of the first embodiment of the present invention, since the shared well regions are insulated from each other by the element isolation insulating film 408, crosstalk and color mixing between the shared well regions can be prevented. Further, in each shared well region, a plurality of pixels (two pixels in the configuration of FIG. 1) share one well contact, so that the area occupied by the well contacts per unit pixel can be reduced. As a result, the photodiode arrangement area can be expanded in the pixel array. As a result, the area of the photodiode can be increased, and the deterioration of image quality can be prevented while maintaining the number of saturated electrons and the quantum efficiency of the pixel.

### Second Embodiment

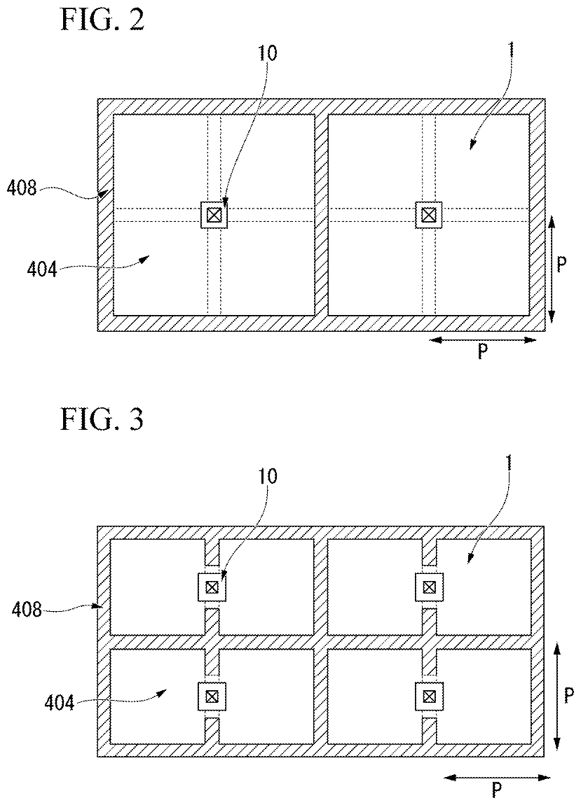

A second embodiment of the present invention will be described. FIG. 2 is a plan view showing the configuration of the pixel array in the solid-state image pickup device according to the second embodiment of the present invention. In the configuration of FIG. 2, of the element isolation insulating film 408 surrounding each unit pixel 1 in FIG. 1, the element isolation insulating film 408 (dotted line portion in the drawing) on two sides separating adjacent pixels is omitted. Accordingly, in the configuration of FIG. 2, one shared well region includes four unit pixels, and the four unit pixels share one well contact.

In a region where the element isolation insulating film 408 is omitted (dotted line portion in the drawing), the well contact 10 shared by the four unit pixels included in the shared well region is disposed. In the configuration of FIG. 2, the well contact 10 is disposed at an intermediate portion between the four unit pixels included in the shared well region.

As described above, the number of unit pixels sharing the well contact is not limited to two, and more unit pixels may share the well contact. By increasing the number of unit pixels sharing a well contact, the area occupied by the well contact per unit pixel can be further reduced. As a result, in the pixel array, the photodiode arrangement area can be further expanded. As a result, the area of the photodiode can be further increased, and the number of saturated electrons and the quantum efficiency of the pixel can be maintained to further prevent image quality deterioration.

### Third Embodiment

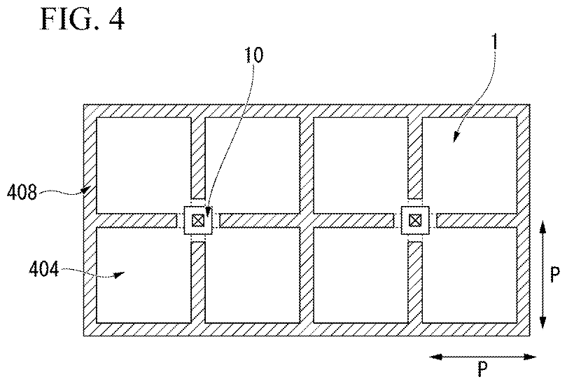

A third embodiment of the present invention will be described. FIGS. 3 and 4 are plan views showing the configuration of the pixel array in the solid-state image pickup device according to the third embodiment of the present invention. In the configuration of FIG. 3, of the element isolation insulating film 408 that separates adjacent pixels in FIG. 1, the element isolation insulating film is omitted only in the region where the well contact is disposed. In the configuration of FIG. 4, of the element isolation insulating film 408 that separates adjacent pixels in FIG. 2, the element isolation insulating film is omitted only in the region where the well contact is disposed.

As described above, in the third embodiment of the present invention, as in the first and second embodiments, occupied area of well contacts per unit pixel is lowered by increasing the number of unit pixels sharing the well contact. As a result, the photodiode arrangement area can be expanded in the pixel array. As a result, the area of the photodiode can be further increased, and the number of saturated electrons and the quantum efficiency of the pixel can be maintained to further prevent image quality deterioration.

Furthermore, in the third embodiment of the present invention, the number of portions where the element isolation insulating film 408 is omitted is minimized, so that the crosstalk and color mixing between adjacent pixels can be further suppressed as compared with the first embodiment and the second embodiment.

### Fourth Embodiment

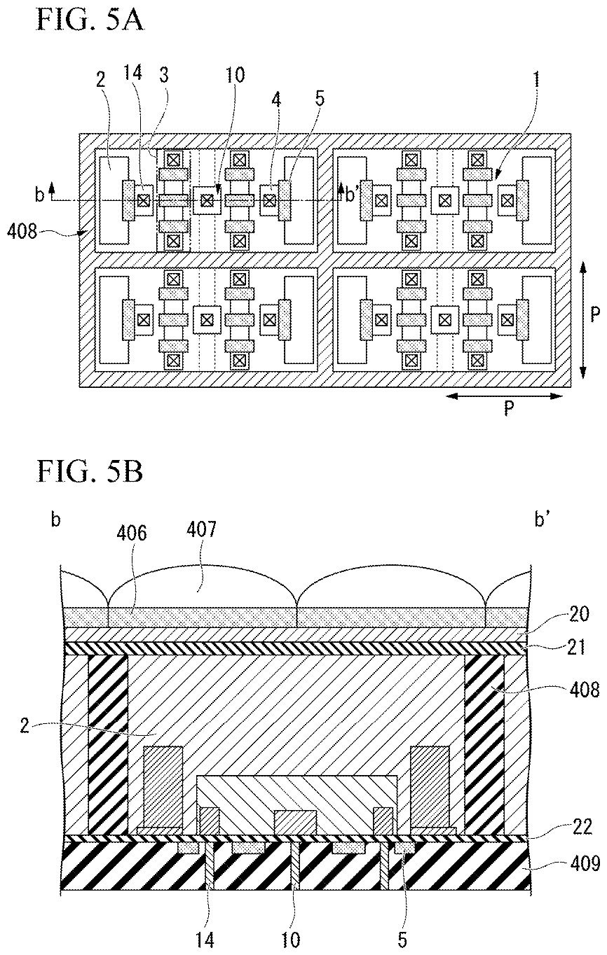

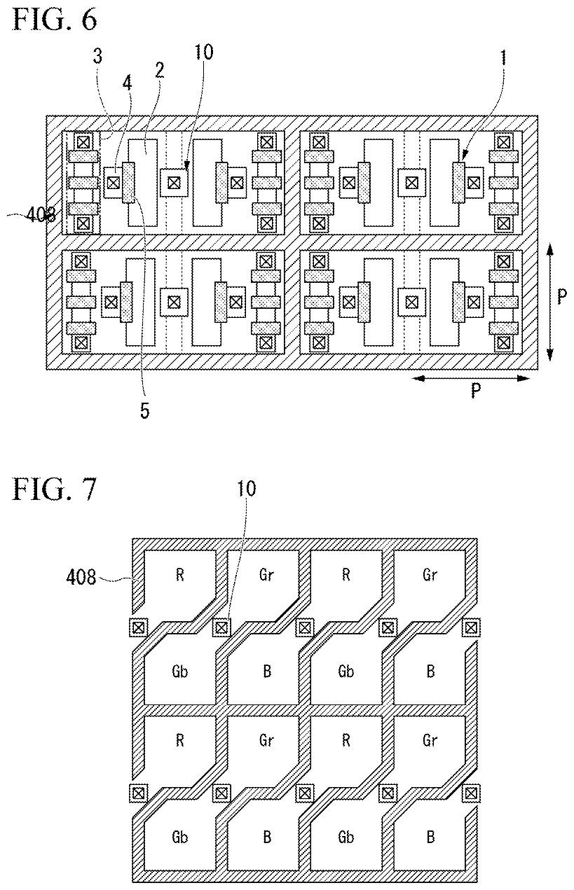

A fourth embodiment of the present invention will be described. In the fourth embodiment of the present invention, the arrangement of pixel transistors and photodiodes in the pixel array is considered. FIGS. 5A and 6 are plan views showing the configuration of the pixel array in the solid-state image pickup device according to the fourth embodiment of the present invention. FIG. 5A and FIG. 6 are obtained by adding a photodiode 2 (photoelectric conversion element), a pixel transistor 3 (circuit element), a floating diffusion 4 and a transfer transistor gate 5 as components to the pixel array of FIG. 1A.

In FIG. 1A, the arrangement of the pixel transistors and the photodiodes in the pixel array is not considered, and thus the pixel transistors and the photodiodes are omitted. However, in reality, components of the pixel transistor 3, the photodiode 2, the floating diffusion 4, and the transfer transistor gate 5 exist in the pixel array of FIG. 1A in the same way.

Here, the pixel transistor 3 is a transistor for driving the pixel, and includes, for example, a reset transistor, an amplifier transistor, a selection transistor, and the like. The photodiode 2 is an element that photoelectrically converts and accumulates charges, and is connected to the floating diffusion 4 via the transfer transistor gate 5. The floating diffusion 4 reads the signal charge from the photodiode 2 and transmits it to the pixel transistor 3 as a signal voltage.

The difference between the configuration of FIG. SA and the configuration of FIG. 6 is that the arrangement of the pixel transistor 3 (circuit element), the photodiode 2 (photoelectric conversion element), the floating diffusion 4 and the transfer transistor gate 5 in the shared well region is different.

In the configuration of FIG. 5A, in the shared well region, the pixel transistors 3 of each unit pixel 1 are arranged to face each other with the well contact 10 interposed therebetween. In the shared well region, the photodiode 2 of each unit pixel is arranged at a position as far as possible from the well contact 10. That is, in the shared well region, the pixel transistor 3 and the photodiode 2 of each unit pixel are arranged symmetrically with respect to the well contact 10.

FIG. 5B is a cross-sectional view showing the configuration of the pixel array in the solid-state image pickup device according to the fourth embodiment of the present invention. Specifically, FIG. 5B is a diagram showing a cross section taken along line b-b′ of FIG. 5A. In the configuration of FIG. 5B, a circuit portion is formed on the surface side (lower side of the drawing) of the semiconductor substrate 404, and a gate insulating film 22 and an interlayer insulating film 409 are formed so as to cover the surface of the semiconductor substrate 404 and the circuit portion. Further, the rear surface side (upper side in the drawing) of the semiconductor substrate 404 is a light receiving surface, where the insulating film 21 and the planarizing film 20 are formed, and the color filter 406 and the microlens 407 are disposed.

The semiconductor substrate 404 is divided into a plurality of shared well regions insulated from each other by an element isolation insulating film 408. A contact P+ for supplying power to the P-well is provided on the front surface side (lower side of the drawing) of the semiconductor substrate 404. The well contact 10 is provided so as to penetrate the interlayer insulating film 409 downward from the contact P+.

Further, a contact 14 is provided on the surface side of the semiconductor substrate 404 (downward in the drawing) so as to penetrate the interlayer insulating film 409 downward from the floating diffusion 4.

By arranging the pixel transistor 3 and the photodiode 2 as shown in FIG. 5A, the photodiode 2 is surrounded by the element isolation insulating film 408 on three sides. Further, in the shared well region, the two photodiodes 2 are located at positions separated from each other. Thereby, there is an advantage that crosstalk and color mixing can be suppressed.

Further, it is easy to change so that two unit pixels 1 in the shared well region share the pixel transistor 3, by using the region where the well contact 10 is not arranged of the region where the element isolation insulating film 408 is omitted (dotted line portion in the drawing).

On the other hand, in the configuration of FIG. 6, in the shared well region, the photodiodes 2 of the unit pixels 1 are arranged to face each other with the well contact 10 interposed therebetween. In the shared well region, the pixel transistor 3 of each unit pixel is arranged at a position as far as possible from the well contact 10. That is, in the shared well region, the pixel transistor 3 and the photodiode 2 of each unit pixel are arranged symmetrically with respect to the well contact 10.

By arranging the pixel transistor 3 and the photodiode 2 as shown in FIG. 6, the position of the well contact 10 and the position of the photodiode 5 become close. This has the advantage that the potential of the photodiode can be made more accurately.

As described above, since the configuration of FIG. 5A and the configuration of FIG. 6 have different advantages, any configuration may be adopted depending on which advantage the designer gives priority to in the characteristics of the pixel. In FIG. 5A and FIG. 6, the element isolation insulating film 408 on one side separating adjacent unit pixels is omitted, but the element isolation insulating film 408 may be omitted only in the region where the well contact is arranged as shown in FIG. 3.

### Fifth Embodiment

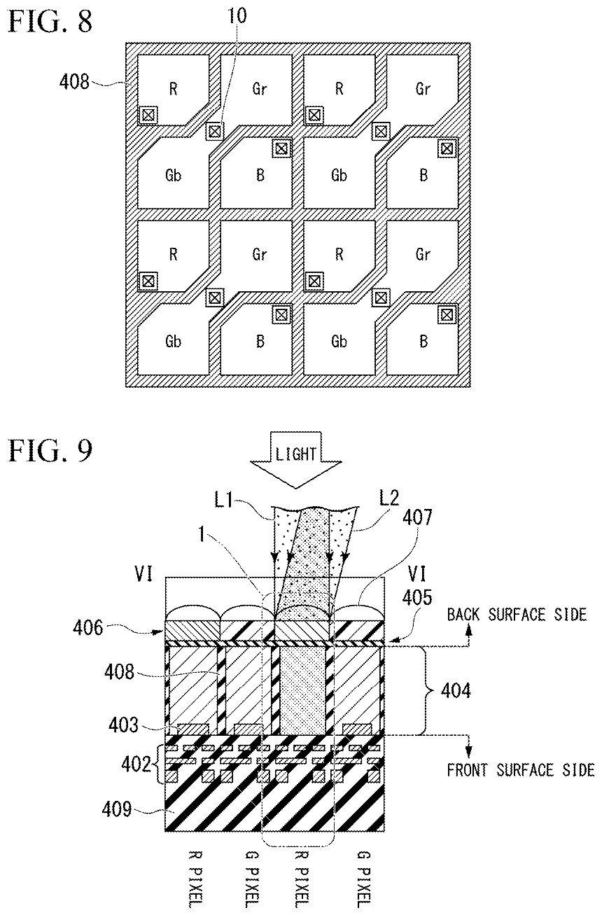

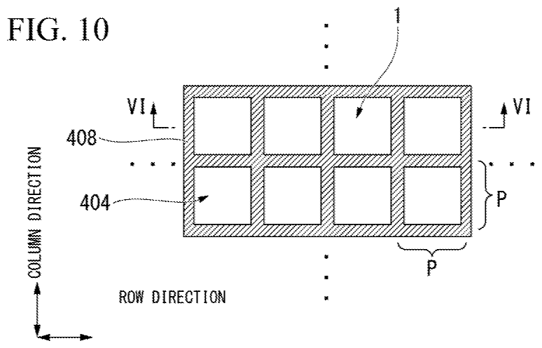

A fifth embodiment of the present invention will be described. In the fifth embodiment of the present invention, the color filter of each unit pixel 1 is considered. FIGS. 7 and 8 are plan views showing the configuration of the pixel array in the solid-state image pickup device according to the fifth embodiment of the present invention. In the configuration of FIG. 7, the well contact 10 is arranged at an intermediate portion between two unit pixels 1 located in a diagonal region on the pixel array. Two unit pixels 1 located in the diagonal region share the well contact 10. The element isolation insulating film 408 is disposed so as to surround the two unit pixels 1 located in the diagonal region and the well contact 10.

Each unit pixel 1 has a color filter. In the configuration of FIG. 7, the arrangement of the color filters in the pixel array is an RGB Bayer arrangement, and the color filters are one of a color filter R that transmits light in the red wavelength region, a color filter G that transmits light in the green wavelength region, and a color filter B that transmits light in the blue wavelength region. Among the color filters G, those adjacent to the color filter R are represented as a color filter Gr, and those adjacent to the color filter B are represented as a color filter Gb.

In the RGB Bayer arrangement, the color filter R, the color filter Gr, the color filter Gb, and the color filter B are arranged as shown in FIG. 7. Therefore, the combination of the color filters of the two unit pixels located in the diagonal region and sharing the well contact 10 is a set of the color filter Gr and the color filter Gb or a set of the color filter R and the color filter B.

Accordingly, the unit pixel having the color filter Gr and the unit pixel having the color filter Gb share the well contact 10. That is, two unit pixels having the same green color filter share the well contact 10. Thereby, there is an advantage that variation in bias potential between unit pixels having color filters of the same color can be suppressed.

FIG. 8 is a modified example of FIG. 7, and the color filter sharing method is different from the configuration of FIG. 7. In the configuration of FIG. 7, the unit pixel having the color filter R and the unit pixel having the color filter B also share the well contact 10. However, as shown in FIG. 8, the unit pixel having the color filter R and the unit pixel having the color filter B may be separated by the element isolation insulating film 408 so that the well contact 10 is not shared.

In the case of the configuration of FIG. 8, the combination of the color filters of two unit pixels sharing the well contact 10 is only a set of the color filter Gr and the color filter Gb. Therefore, since only two unit pixels having the same green color filter share the well contact 10, it is more effective in suppressing variation in bias potential between unit pixels. Further, even if light incident on one unit pixel leaks to the other unit pixel, it is difficult to mix colors.

As described above, although preferred embodiments of the present invention were described, this invention is not limited to these embodiments and their modifications. Additions, omissions, substitutions, and other modifications can be made without departing from the scope of the present invention. For example, the number of unit pixels sharing a well contact can be any number. Further, the circuit configuration in the unit pixel is not limited to the above embodiments.

In the present specification, words indicating directions such as “front, rear, up, down, right, left, vertical, horizontal, row and column” are used to describe these directions in the device of the present invention. Accordingly, these terms used to describe the specification of the present invention should be interpreted relatively in the device of the present invention.

The present invention can be applied to various solid-state image pickup devices, and can efficiently prevent crosstalk and color mixing between adjacent pixels while maintaining the number of saturated electrons and quantum efficiency of the pixels and preventing image quality deterioration.

What is claimed is:

1. A solid-state image pickup device including a two-dimensional pixel array in which unit pixels are arranged on a semiconductor substrate, the unit pixels respectively including photoelectric conversion elements configured to convert inputted light into electric signals, and circuit elements configured to read out the electric signals that have been converted,
wherein the unit pixels are formed in at least one shared well region surrounded by an insulating element isolation region that penetrates the semiconductor substrate from front surface to rear surface and isolates elements from each other, and
each of the shared well region is biased to a predetermined potential via well contact sections of a number that is smaller than that of the unit pixels.

2. The solid-state image pickup device according to claim 1, wherein each of the well contact sections is disposed at an intermediate portion between the unit pixels formed in the shared well region.

3. The solid-state image pickup device according to claim 1, wherein the number of the unit pixels formed in one shared well region is two.

4. The solid-state image pickup device according to claim 1, wherein the number of the unit pixels formed in one shared well region is four.

5. The solid-state image pickup device according to claim 1, wherein the unit pixels formed in at least one shared well region are configured to have a color filter of one color.

6. The solid-state image pickup device according to claim 3, wherein the number of the well contact sections in one shared well region is one, and the photoelectric conversion elements and the circuit elements of the unit pixels are arranged symmetrically with respect to the well contact sections.

7. The solid-state image pickup device according to claim 3, wherein color filters of the two unit pixels formed in one shared well region are a combination that is less affected by color mixing depending on arrangement of the color filters in the pixel array.

8. The solid-state image pickup device according to claim 7, wherein array of the color filters in the pixel array is RGB Bayer array, and two G pixels located in a diagonal region in the pixel array are formed in one shared well region.
